(19) United States
(12) Patent Application Publication
(10) Pub. No.: US 2021/0130689 A1
(43) Pub. Date: May 6, 2021

(54) PHOSPHOR, PRODUCTION METHOD FOR SAME, AND LIGHT-EMITTING DEVICE

(71) Applicant: DENKA COMPANY LIMITED, Tokyo (JP)

(72) Inventors: Masato AKABANE, Machida City (JP); Ryo YOSHIMATU, Machida City (JP); Hiroaki TOYOSHIMA, Machida City (JP); Motoi TANAKA, Tokyo (JP)

(73) Assignee: Denka Company Limited, Tokyo (JP)

(21) Appl. No.: 17/041,920

(22) PCT Filed: Mar. 14, 2019
(86) PCT No.: PCT/JP2019/010705

§ 371 Date: Sep. 25, 2020

(30) Foreign Application Priority Data
Mar. 28, 2018 (JP) 2018-063079

(51) Int. Cl. C09K 11/77; C09K 11/08; C01B 21/082; H01L 33/50

(52) U.S. Cl. CPC C09K 11/77346; C09K 11/0883; C01P 2002/72; H01L 33/502; C01P 2002/54; C01B 21/0825

(57) ABSTRACT

A phosphor including a fired product having a composition represented by general formula M¹ₐM²_{b}M³_{c}Al₃N_{4-d}O_{d}, wherein M¹ is one or more elements selected from Sr, Mg, Ca, and Ba, M² is one or more elements selected from Li, Na, and K, and M³ is one or more elements selected from Eu, Ce, and Mn, and wherein a, b, c, and d satisfy each of the following formulas: 0.850≤a≤1.150, 0.850≤b≤1.150, 0.001≤c≤0.010, 0.10<d≤0.20, and 0.09≤d/(a+d)<0.20.

### TECHNICAL FIELD

The present invention relates to a phosphor for an LED (Light Emitting Diode) or an LD (Laser Diode), a production method for the same, and a light-emitting device using the phosphor.

### BACKGROUND ART

A light-emitting device formed by combining a light emitting diode (LED) and a phosphor is widely used for a lighting device, a backlight of a liquid crystal display device or the like. In particular, when a light-emitting device is used for a liquid crystal display device, high color reproducibility is required, and therefore it is desirable to use a phosphor having a narrow full width at half maximum (hereinafter simply referred to as “half width”) of the fluorescence spectrum.

As a conventionally used red phosphor having a narrow half width, a nitride phosphor or an oxynitride phosphor activated with Eu²⁺ is known. These typical pure nitride phosphors include Sr₂Si₅N₈:Eu²⁺, CaAlSiN₃:Eu²⁺ (abbreviated as CASN), (Ca,Sr)AlSiN₃:Eu²⁺ (abbreviated as SCASN), and the like. The CASN phosphor and the SCASN phosphor have peak wavelengths in the range of 610 to 680 nm, and their half widths are relatively narrow at 75 to 90 nm. However, when these phosphors are used as a light-emitting device for liquid crystal display, further expansion of the color reproduction range is desired, and phosphors having a narrower half width are desired.

Recently, SrLiAl₃N₄:Eu²⁺ (abbreviated as “SLAN”) phosphor is known as a new narrow band red phosphor having a half width of 70 nm or less, and a light-emitting device using this phosphor is expected to have excellent color rendering properties and color reproducibility.

Patent Literature 1 discloses a production method for a nitride phosphor containing a fired product having a characteristic composition and having an oxygen element content of 2 to 4% by mass. It is disclosed that the phosphor obtained by the method can be considered to have a compound different from the composition of the phosphor on at least a part of the surface, so that, for example, the refractive index is adjusted near the surface of the particles of the phosphor, thereby efficiently extracting light and thus increasing the emission intensity of the phosphor.

However, since the emission efficiency of the SLAN phosphor is still low at present, further improvement of emission intensity is required for practical use.

### CITATION LIST

### Patent Literature

Patent Literature 1: Japanese Patent Laid-Open No. 2017-88881

### SUMMARY OF INVENTION

### Technical Problem

It is an object of the present invention to provide an SLAN phosphor that can realize a higher emission (luminescenece) intensity (also referred to as emission peak intensity) than a conventional SLAN phosphor while keeping the half width to the same extent, that is, 70 nm or less.

### Solution to Problem

As a result of keenly investigating the relationship between the emission intensity and the composition ratio of each element contained in the SLAN phosphor containing oxygen content, the inventors have found that the phosphor has excellent emission intensity when each element contained in the phosphor satisfies a specific relationship, which led to the completion of the present invention together with the invention of the aforementioned phosphor of the present invention and the production method for the same.

That is, the present invention is specified as follows.

(1) A phosphor comprising a fired (sintered) product having a composition represented by general formula M¹ₐM²_{b}M³_{c}Al₃N_{4-d}O_{d}, wherein M¹ is one or more elements selected from Sr, Mg, Ca, and Ba, M² is one or more elements selected from Li, Na, and K, and M³ is one or more elements selected from Eu, Ce, and Mn, and wherein a, b, c, and d satisfy each of the following formulas:

0.850≤a≤1.150,

0.850≤b≤1.150,

0.001≤c≤0.010,

0.10<d≤0.20, and

0.09≤d/(a+d)<0.20.

(2) The phosphor according to (1), wherein the M¹ includes at least Sr, the M² includes at least Li, and the M³ includes at least Eu.
(3) The phosphor according to (1) or (2), wherein the phosphor has a diffuse reflectance of light irradiated at a wavelength of 300 nm of 56% or more and a diffuse reflectance at a peak wavelength of a fluorescence spectrum of 90% or more.
(4) The phosphor according to any of (1) to (3), wherein when excited by blue light at 455 nm wavelength, the phosphor has a peak wavelength in a range of 640 nm or more and 670 nm or less and a half width of 45 nm or more and 60 nm or less.
(5) The phosphor according to any of (1) to (4), wherein when excited by blue light at 455 nm wavelength, the phosphor has a color purity of emission color with an x value of 0.680≤x<0.735 in a CIE-xy chromaticity diagram.
(6) A production method for the phosphor according to any of (1) to (5), comprising:
a mixing step of mixing raw materials,
a firing step of firing the mixture obtained by the mixing step,
an acid treatment step of mixing the fired product obtained by the firing step and an acid solution,
wherein, in the mixing step, the M¹ is charged in an amount of 1.10 or more and 1.20 or less when the Al is in an amount of substance of 3.
   (7) A light-emitting device having the phosphor according to any one of (1) to (5) and a light-emitting element.

### Advantageous Effects of Invention

The phosphor of the present invention can realize a higher emission intensity as compared with the conventional SLAN phosphor while keeping the half width to the same extent.

### BRIEF DESCRIPTION OF DRAWINGS

FIG. 1 is XRD measurement results of Example 2 and Comparative Example 4.

FIG. 2 is fluorescence spectra of Examples 1 to 3 and Comparative Examples 3 to 5.

FIG. 3 is diffuse reflectance spectra of Example 2 and Comparative Example 4.

### DESCRIPTION OF EMBODIMENTS

The phosphor according to the embodiment of the present invention has the general formula M¹ₐM²_{b}M³_{c}Al₃N_{4-d}O_{d}. In the formula, a, b, c, 3, 4-d, and d shown as subscripts indicate the amounts of substance of the corresponding elements. In the following description, the amount of substance is shown based on the formula.

M¹ is one or more elements selected from Sr, Mg, Ca, and Ba. Preferably, M¹ includes at least Sr. From the viewpoint of crystal structure stability, the amount of substance a of M¹ is in the range of 0.850 or more and 1.150 or less, preferably in the range of 0.900 or more and 1.100 or less. The amount of substance a of M¹ is more preferably in the range of 0.950 or more and 1.050 or less.

M² is one or more elements selected from Li, Na, and K. Preferably, M² includes at least Li. From the viewpoint of crystal structure stability, the amount of substance b of M² is in the range of 0.850 or more and 1.150 or less, preferably in the range of 0.900 or more and 1.100 or less. The amount of substance b of M² is more preferably in the range of 0.950 or more and 1.050 or less.

M³ is an activator added to the host crystal, that is, an element that constitutes the emission center ion of the phosphor, and is one or more elements selected from Eu, Ce, and Mn. M³ can be selected according to the required emission wavelength, and preferably includes at least Eu.

If the amount of substance of M³ is too small, sufficient emission peak intensity cannot be obtained, and if it is too large, concentration quenching tends to be large and emission peak intensity tends to be low, and as a result, a phosphor with high brightness cannot be obtained. Therefore, the amount of substance c of M³ is 0.001 or more and 0.010 or less.

In the above general formula, the amount of substance d of oxygen is in the range of more than 0.10 and 0.20 or less, preferably in the range of 0.11 or more and 0.18 or less. Considering the amount of oxygen derived from the raw materials, it is difficult to set d to 0.10 or less, and if d exceeds 0.20, the crystalline state of the SLAN phosphor becomes unstable, which may cause a decrease in emission intensity.

The content of the oxygen element in the phosphor is preferably in the range of less than 2% by mass, more preferably 1.3% by mass or less. When the content of oxygen element is 2% by mass or more, the emission intensity is lowered for the same reason as above.

The value of d/(a+d) calculated from the amount of substance of M¹ and oxygen, i.e., a and d, is in the range of 0.09 or more and less than 0.20, preferably in the range of 0.09 or more and 0.18 or less, more preferably in the range of 0.10 or more and 0.16 or less. Considering the amount of oxygen derived from the raw materials, it is difficult to make d/(a+d) less than 0.09, and if d/(a+d) exceeds 0.20, the crystalline state of the SLAN phosphor becomes unstable, which may cause a decrease in emission intensity.

It is preferable that the phosphor has a diffuse reflectance of 56% or more for irradiation with light having a wavelength of 300 nm, and a diffuse reflectance of 90% or more at the peak wavelength of the fluorescence spectrum. With these characteristics, the emission efficiency is further increased and the emission intensity is improved.

It is preferable that the phosphor has a peak wavelength in the range of 640 nm or more and 670 nm or less and a half width of 45 nm or more and 60 nm or less when excited by blue light having a wavelength of 455 nm. With these characteristics, excellent color rendering properties and color reproducibility can be expected.

It is preferable that the phosphor has an x value of 0.680≤x<0.735 in the CIE-xy chromaticity diagram for the color purity of the emission color when excited by blue light having a wavelength of 455 nm. With these characteristics, excellent color rendering properties and color reproducibility can be expected. If the x value is 0.680 or more, red emission with good color purity can be further expected, and the x value of 0.735 or more exceeds the maximum value in the CIE-xy chromaticity diagram, so it is preferable to meet the above range.

The phosphor can be produced by a mixing step of mixing raw materials, a firing (or sintering) step of firing the mixture obtained by the mixing step, and an acid treatment step of mixing the fired product obtained by the firing step and an acid solution. In addition, it is preferable to add a crushing step of crushing the fired product and an annealing step. Impurities remaining on the surface of the produced phosphor can be dissolved and removed in the acid treatment step, and defects in the crystal can be removed in the annealing step to increase the emission intensity.

In order to increase the emission intensity, it is necessary that the amount of M¹ charged (that is, the amount of substance of M¹ charged into the raw materials to be mixed) is 1.10 or more when the amount of substance of Al is 3 in the mixing step. It is presumed that if the amount of M¹ charged is less than 1.10, the amount of M¹ in the phosphor will be insufficient due to volatilization of M¹ during the firing step, etc., causing M¹ defects, which will break the symmetry of the crystal structure and prevent the phosphor from exhibiting narrow-band fluorescence spectra, resulting in a decrease in emission intensity. In the mixing step, it is necessary that the amount of M¹ charged is 1.20 or less when the amount of substance of Al is 3. When the amount of M¹ charged is more than 1.20, the amount of different phases containing M¹ increases, and it becomes difficult to remove the different phases even after the acid treatment step, which causes a decrease in emission intensity.

In the acid treatment step, the acid liquid is preferably an aqueous solution, and the contact with the acid liquid is generally performed by dispersing the phosphor in an aqueous acid solution containing, for example, one or more of nitric acid, hydrochloric acid, acetic acid, sulfuric acid, formic acid, and phosphoric acid, and stirring it for several minutes to several hours.

Specifically, the phosphor can be dispersed in a mixed solution of an organic solvent and an acid solution, stirred for several minutes to several hours, and then washed with an organic solvent. By the acid treatment, the impurity elements contained in the raw material, the impurity elements derived from the firing container, the different phases generated in the firing step, and the impurity elements mixed in in the crushing step can be dissolved and removed. At the same time, it is also possible to remove the fine powder, thus, the scattering of light is suppressed and the absorptivity of the phosphor is also improved.

As the organic solvent, alcohols such as methanol, ethanol, and 2-propanol and ketones such as acetone can be used. The acid solution is one or more of nitric acid, hydrochloric acid, acetic acid, sulfuric acid, formic acid, and phosphoric acid. The mixing ratio of these solutions is, for example, adjusted so that the acid solution has a concentration of 0.1 to 3 vol % with respect to the organic solvent.

The light-emitting device according to the embodiment of the present invention may have the phosphor and the light-emitting element according to the above embodiments.

As the light-emitting element, an ultraviolet LED, a blue LED, and a fluorescent lamp can be used alone or in combination. The light-emitting element which emits light having a wavelength of 250 nm or more and 550 nm or less is desirable, and a blue LED light-emitting element having a wavelength of 420 nm or more and 500 nm or less is especially preferable.

As the phosphor used in the light-emitting device, in addition to the phosphor according to the above embodiment, phosphors having other emission colors can be used together. Such other emission color phosphors include a blue light-emitting phosphor, a green light-emitting phosphor, a yellow light-emitting phosphor, and an orange light-emitting phosphor, such as Ca₃Sc₂Si₃O₁₂:Ce, CaSc₂O₄:Ce, Y₃Al₅O₁₂:Ce, Tb₃Al₅O₁₂:Ce, (Sr, Ca, Ba)₂SiO₄:Eu, La₃Si₆N₁₁:Ce, and Ba₂Si₅N₈:Eu. The phosphor that can be used in combination with the phosphor of the present invention is not particularly limited and can be appropriately selected according to the brightness, color rendering properties, and the like required of the light-emitting device. By mixing the phosphor of the present invention with the phosphors of other emission colors, white in various color temperatures ranging from neutral white to light bulb color can be realized.

The light-emitting device includes a lighting device, a backlight device, an image display device, and a signal device.

The light-emitting device can realize high emission intensity by adopting the phosphor according to the embodiment of the present invention.

### EXAMPLES

Hereinafter, the present invention will be described in more detail with reference to the following examples. However, the following examples partially illustrate the embodiments of the present invention and do not limit the scope of the present invention.

### Example 1

In order to obtain a phosphor having a composition represented by M¹ₐM²_{b}M³_{c}Al₃N_{4-d}O_{d} and satisfying M¹=Sr, M²=Li, and M³=Eu, Sr₃N₂ (manufactured by TAIHEIYO CEMENT CORPORATION), Li₃N (manufactured by Materion), AlN (manufactured by Tokuyama Corporation), and Eu₂O₃ (manufactured by Shin-Etsu Chemical Co., Ltd.) were used as the respective raw materials. In the air, AlN and Eu₂O₃ were weighed and mixed, and then the aggregate mixture was disintegrated through a nylon sieve having a mesh opening of 250 μm to obtain a pre-mixture.

The pre-mixture was moved into a glove box holding an inert atmosphere with water of 1 mass ppm or less and oxygen of 1 mass ppm or less. Then, the above Sr₃N₂ and Li₃N were weighed so that the value of a would be 10% excess and the value of b would be 20% excess in stoichiometric ratio, then added to the pre-mixture and mixed, and further the aggregate mixture was disintegrated through a nylon sieve having a mesh opening of 250 μm to obtain a raw mixture of the phosphor. Since Sr and Li are easily scattered during firing, they were added in larger amounts than the theoretical values.

Next, the raw mixture was filled in a cylindrical BN container (manufactured by Denka Company Limited) with a lid.

Next, the container filled with the raw material mixture of the phosphor was taken out from the glove box, then set in an electric furnace (manufactured by Fuji Dempa Kogyo Co., Ltd.) with a carbon heater equipped with a graphite heat insulating material, and a firing step was performed.

To start the firing step, the inside of the electric furnace was once degassed to a vacuum state, and then firing was started from room temperature under a pressurized nitrogen atmosphere of 0.8 MPa·G. After the temperature in the electric furnace reached 1200° C., firing was continued while maintaining the temperature for 8 hours, and then cooled to room temperature. The obtained phosphor was crushed in a mortar and then classified with a nylon sieve having an opening of 75 and collected.

As a step of acid treatment, the powder was added to a mixed solution of HNO₃ (60%) (Wako Pure Chemical Industries, Ltd.) in MeOH (99%) (Kokusan Kagaku Co., Ltd.), and the mixture was stirred and then classified to obtain the phosphor powder of Example 1. The oxygen content of the phosphor according to Example 1 was 1.0% by mass.

### Examples 2 and 3

In Examples 2 and 3, phosphor powders were obtained under the same conditions as in Example 1, except that the amount of substance of charged Sr was changed as shown in Table 1. The oxygen contents of the phosphors according to Examples 2 and 3 were 0.8% by mass and 1.1% by mass, respectively.

### Comparative Examples 1 to 7

In Comparative Examples 1 to 7, phosphor powders were obtained under the same conditions as in Example 1, except that the amount of substance of charged Sr was changed as shown in Table 1 and the presence or absence of acid treatment was changed as shown in Table 1. The oxygen contents of the phosphors according to Comparative Examples 1 to 7 were 2.2% by mass, 1.4% by mass, 1.5% by mass, 1.7% by mass, 2.3% by mass, 1.9% by mass, and 1.6% by mass, respectively.

### Composition

In order to obtain the chemical composition (i.e., general formula: M¹ₐM²_{b}M³_{c}Al₃N_{4-d}O_{d}) of the total crystalline phases of all the phosphor samples obtained in Examples and Comparative Examples, the subscripts a to d for respective elements were obtained by analyzing the obtained phosphors by the following method. The results of the analysis of Sr, Li, Al, and Eu were obtained using an ICP atomic emission spectrometer (CIROS-120 manufactured by SPECTRO), and those of O and N were obtained using an oxygen-nitrogen analyzer (EMGA-920 manufactured by HORIBA, Ltd.) for calculation. Table 1 shows the numerical values of a to d for the phosphors of Examples and Comparative Examples.

### x Value of CIE Chromaticity Diagram

The chromaticity x was measured by a spectrophotometer (MCPD-7000 manufactured by Otsuka Electronics Co., Ltd.) and calculated by the following procedure. All the phosphor samples obtained in the Examples and Comparative Examples were filled so that the surface of the concave cell was smooth, and an integrating sphere was attached. Monochromatic light separated into a wavelength of 455 nm from an emission light source (Xe lamp) was introduced into the integrating sphere using an optical fiber. The phosphor sample was irradiated with this monochromatic light as an excitation source, and the fluorescence spectrum of the sample was measured. Chromaticity x is the CIE chromaticity coordinate x value (chromaticity x) in the XYZ color system defined by JIS Z 8781-3:2016 according to JIS Z 8724:2015, which was calculated from the wavelength range data of the fluorescence spectrum from 465 nm to 780 nm. When the standard sample NSG1301 sold by Sialon Co., Ltd. was measured using the above measurement method, the external quantum efficiency was 55.6%, the internal quantum efficiency was 74.8%, and the chromaticity x was 0.356. The device is calibrated using this sample as a standard sample.

### Fluorescence Peak Wavelength, Half Width, Relative Emission Intensity

For all the phosphor samples obtained in Examples and Comparative Examples, the emission intensity of the phosphors was measured using a spectrofluorometer (F-7000 manufactured by Hitachi High-Technologies Corporation) corrected with rhodamine B and a sub-standard light source. That is, the fluorescence spectrum at an excitation wavelength of 455 nm was measured using the solid sample holder attached to the photometer.

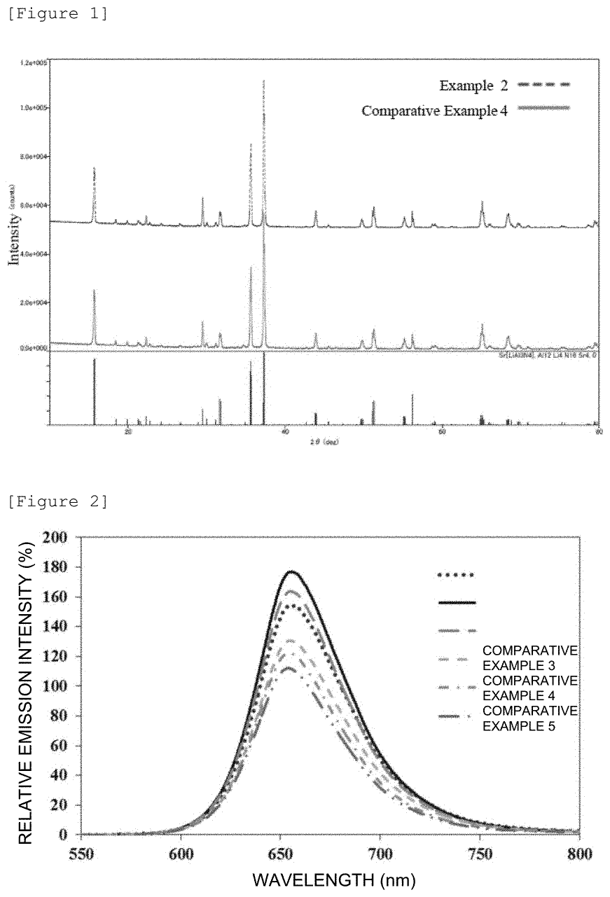

The peak wavelength of the fluorescence spectrum of each of the phosphors of Examples and Comparative Examples was in the range of 650 nm to 660 nm. The intensity value at the peak wavelength of the fluorescence spectrum was defined as the emission intensity of the phosphor, and the emission intensity of Comparative Example 1 was set to 100%, and the emission intensities of other Examples and Comparative Examples were converted into relative ratios based on this, which are shown in Table 1 and FIG. 2. The half widths of the fluorescence spectra were also measured and are also shown in Table 1. Note that the characteristics were judged to be excellent if the relative emission intensity exceeded 140% while maintaining the half width of 70 nm or less.

### Diffuse Reflectance

The diffuse reflectance of the phosphor was measured for all the phosphor samples obtained in Examples and Comparative Examples by an instrument consisting of an ultraviolet-visible spectrophotometer (V-550, manufactured by JASCO Corporation) with an integrating sphere device (manufactured by JASCO Corporation, ISV-469) attached. Baseline correction with a standard reflection plate (Spectralon manufactured by Labsphere) was performed, a sample holder filled with phosphor powder was set, a single wavelength light in the wavelength range of 220 to 850 nm was irradiated while changing the wavelength, and the diffuse reflectance of each wavelength was measured. These results are also shown in Table 1.

TABLE 1

| | | | | | | | Diffuse reflectance | | Fluorescence | x value of | Relative | |
|---|---|---|---|---|---|---|---|---|---|---|---|---|
| | Charged | Phosphor composition (subscripts of | | | | | (%) | | peak | CIE | emission | Half |
| | Sr | general formula), and value of d/(a + d) | | | | | | Peak | wavelength | chromaticity | intensity | width |
| | ratio *1 | a | b | c | d | d/(a + d) | 300 nm | wavelength | (nm) | diagram | (%) *2 | (nm) |
| Comparative | 1.00 | 0.938 | 0.972 | 0.005 | 0.35 | 0.27 | 54.2 | 93.2 | 656 | 0.698 | 100 | 61 |
| Example 1 | | | | | | | | | | | | |
| Comparative | 1.05 | 1.000 | 1.002 | 0.005 | 0.21 | 0.17 | 52.7 | 92.8 | 656 | 0.702 | 117 | 57 |
| Example 2 | | | | | | | | | | | | |
| Comparative | 1.10 | 1.046 | 1.027 | 0.005 | 0.24 | 0.18 | 55.0 | 90.8 | 654 | 0.694 | 130 | 53 |
| Example 3 | | | | | | | | | | | | |
| Comparative | 1.15 | 1.069 | 1.012 | 0.005 | 0.28 | 0.21 | 55.3 | 88.0 | 654 | 0.691 | 123 | 52 |
| Example 4 | | | | | | | | | | | | |
| Comparative | 1.20 | 1.082 | 1.001 | 0.004 | 0.38 | 0.26 | 53.2 | 87.6 | 654 | 0.686 | 112 | 52 |
| Example 5 | | | | | | | | | | | | |
| Comparative | 1.00 | 0.907 | 0.966 | 0.004 | 0.29 | 0.24 | 53.2 | 93.3 | 656 | 0.709 | 115 | 61 |
| Example 6 | | | | | | | | | | | | |
| Comparative | 1.05 | 0.934 | 0.977 | 0.004 | 0.24 | 0.20 | 51.8 | 93.1 | 656 | 0.702 | 131 | 58 |
| Example 7 | | | | | | | | | | | | |
| Example 1 | 1.10 | 0.959 | 1.023 | 0.003 | 0.15 | 0.13 | 58.3 | 94.4 | 656 | 0.688 | 154 | 54 |
| Example 2 | 1.15 | 0.963 | 1.023 | 0.003 | 0.12 | 0.11 | 59.5 | 93.4 | 656 | 0.710 | 177 | 52 |
| Example 3 | 1.20 | 0.972 | 1.017 | 0.003 | 0.16 | 0.15 | 58.6 | 93.1 | 655 | 0.691 | 149 | 52 |

*1 Amount of substance of Sr when the amount of substance of Al is 3.
*2 Relative emission intensity when the emission intensity of Comparative Example 1 is 100%.

Powder X-ray diffraction analysis (XRD) using CuKα rays was performed on all the phosphor samples obtained in Examples and Comparative Examples using an X-ray diffractometer (Ultima IV manufactured by Rigaku Corporation). The obtained X-ray diffraction patterns show a SrLiAl₃N₄ crystalline phase, and a slight amount of SrO and a diffraction pattern which is difficult to determine qualitatively as different phases in Comparative Examples 1 to 5.

The measurement results of Example 2 and Comparative Example 4 are shown in FIG. 1. From the XRD measurement results, by comparing Example 2 and Comparative Example 4, it can be seen that different phases such as SrO can be dissolved and removed by the acid treatment step, resulting in a single phase SLAN phosphor.

Examples 1 to 3, which meet each of the requirements of the present invention, also have small half widths and higher relative emission intensities than the phosphors of Comparative Examples 1 to 7. The phosphors of Examples 1 to 3 are samples obtained by subjecting the phosphors of Comparative Examples 3 to 5 to acid treatment, respectively, and it can be seen that the emission intensity is increased in all samples. It is considered that this is because the oxygen content could be reduced by removing the different phase and the fine powder contained in the sample by the acid treatment step.

It can be seen that the SLAN phosphor having high emission intensity may be obtained by performing the acid treatment step as described above and setting the amount of oxygen and the amount of substance of charged Sr within the ranges of the present invention. Since the half width is also narrowed, excellent color rendering properties and color reproducibility can be realized.

The fluorescence spectra of Examples 1 to 3 and Comparative Examples 3 to 5 are shown in FIG. 2. The relative emission intensities were calculated based on Comparative Example 1. In Examples 1 to 3 in which the acid treatment was performed, the relative emission intensities were higher than in Comparative Examples 3 to 5 in which the acid treatment was not performed.

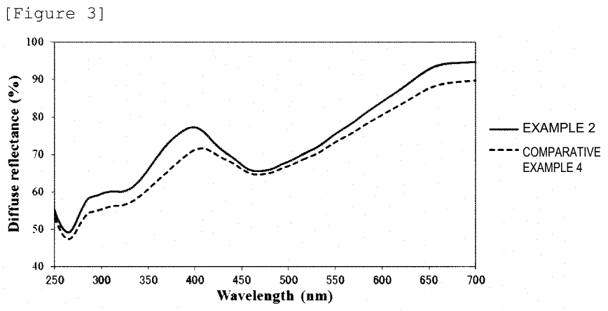

The diffuse reflectance spectra of Example 2 and Comparative Example 4 are shown in FIG. 3. In Example 2 in which the acid treatment was performed, the diffuse reflectance at 300 nm and the emission peak wavelength showed high values, compared with Comparative Example 4 in which the acid treatment was not performed. It is presumed that the diffuse reflectance was improved because the different phase such as SrO was removed by the acid treatment step.

1. A phosphor comprising a fired product having a composition represented by general formula M¹ₐM²_{b}M³_{c}Al₃N_{4-d}O_{d},
wherein M¹ is one or more elements selected from Sr, Mg, Ca, and Ba, M² is one or more elements selected from Li, Na, and K, and M³ is one or more elements selected from Eu, Ce, and Mn, and
wherein a, b, c, and d satisfy each of the following formulas:
0.850≤a≤1.150,
0.850≤b≤1.150,
0.001≤c≤0.010,
0.10<d≤0.20, and
0.09≤d/(a+d)<0.20.

2. The phosphor according to claim 1, wherein the M¹ includes at least Sr, the M² includes at least Li, and the M³ includes at least Eu.

3. The phosphor according to claim 1, wherein the phosphor has a diffuse reflectance of light irradiated at a wavelength of 300 nm of 56% or more and a diffuse reflectance at a peak wavelength of a fluorescence spectrum of 90% or more.

4. The phosphor according to claim 1, wherein when excited by blue light at 455 nm wavelength, the phosphor has a peak wavelength in a range of 640 nm or more and 670 nm or less and a half width of 45 nm or more and 60 nm or less.

5. The phosphor according to claim 1, wherein when excited by blue light at 455 nm wavelength, the phosphor has a color purity of emission color with an x value of 0.680≤x<0.735 in a CIE-xy chromaticity diagram.

6. A production method for the phosphor according to claim 1 comprising:
a mixing step of mixing raw materials,
a firing step of firing the mixture obtained by the mixing step,
an acid treatment step of mixing the fired product obtained by the firing step and an acid solution,
wherein, in the mixing step, the M¹ is charged in an amount of 1.10 or more and 1.20 or less when the Al is in an amount of substance of 3.

7. A light-emitting device having the phosphor according to claim 1 and a light-emitting element.
